(19) United States
(12) Patent Application Publication
(10) Pub. No.: US 2014/0334122 A1
(43) Pub. Date: Nov. 13, 2014

(54) RISER CARD ASSEMBLY

(71) Applicants: HON HAI PRECISION INDUSTRY CO., LTD., New Taipei (TW); HONG FU JIN PRECISION INDUSTRY (ShenZhen) CO., LTD., ShenZhen (CN)

(72) Inventors: BO TIAN, Shenzhen (CN); KANG WU, Shenzhen (CN); YU HAN, Shenzhen (CN)

(73) Assignees: HONG FU JIN PRECISION INDUSTRY (ShenZhen) CO., LTD., Shenzhen (CN); HON HAI PRECISION INDUSTRY CO., LTD., New Taipei (TW)

(21) Appl. No.: 13/901,596

(22) Filed: May 24, 2013

(30) Foreign Application Priority Data
May 10, 2013 (CN) 201310169787X

(51) Int. Cl. H05K 7/12

(52) U.S. Cl. CPC H05K 7/12
USPC 361/801

(57) ABSTRACT

A riser card assembly includes two riser cards and two fixing members. Each riser card includes a plate, a first connector connected to a top side of the plate, a second connector connected to a side of the plate, and an edge connector extending from a bottom side of the plate. The riser cards are fixed to sides of the fixing members. A pin and a receiving portion are formed at a side of each fixing member. Each edge connector and the corresponding pin are capable of being engaged in the first connector of the other riser card and the corresponding receiving portion.

### BACKGROUND

1. Technical Field

The present disclosure relates to a riser card assembly including at least two riser cards.

2. Description of Related Art

Different types of servers need different riser cards with a different number of connectors. As a result, when a server is produced, riser cards are produced to fit to this server, which will increase the cost.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an embodiment of a riser card assembly, together with a motherboard, wherein the riser card assembly includes a fixing member.

FIG. 2 is similar to FIG. 1, but viewed from another perspective.

FIG. 3 is an enlarged view of the fixing member of FIG. 2.

FIG. 4 is an assembled, isometric view of FIG. 1.

FIG. 5 is similar to FIG. 4, but viewed from another perspective.

FIG. 6 is an enlarged view of another fixing member.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

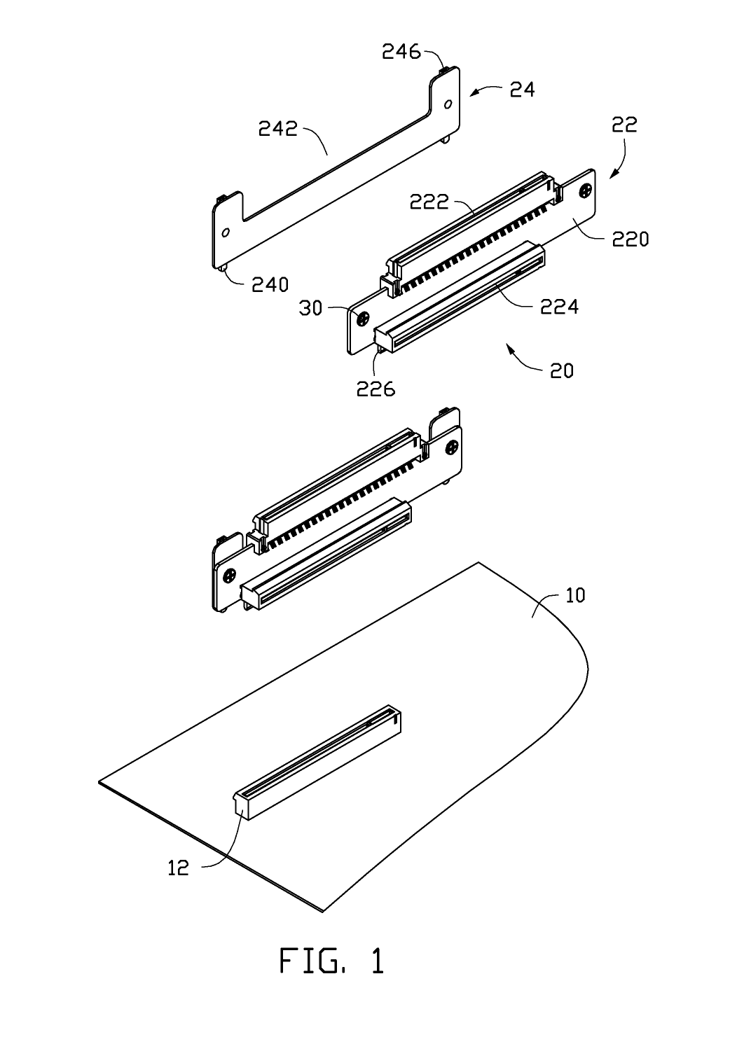

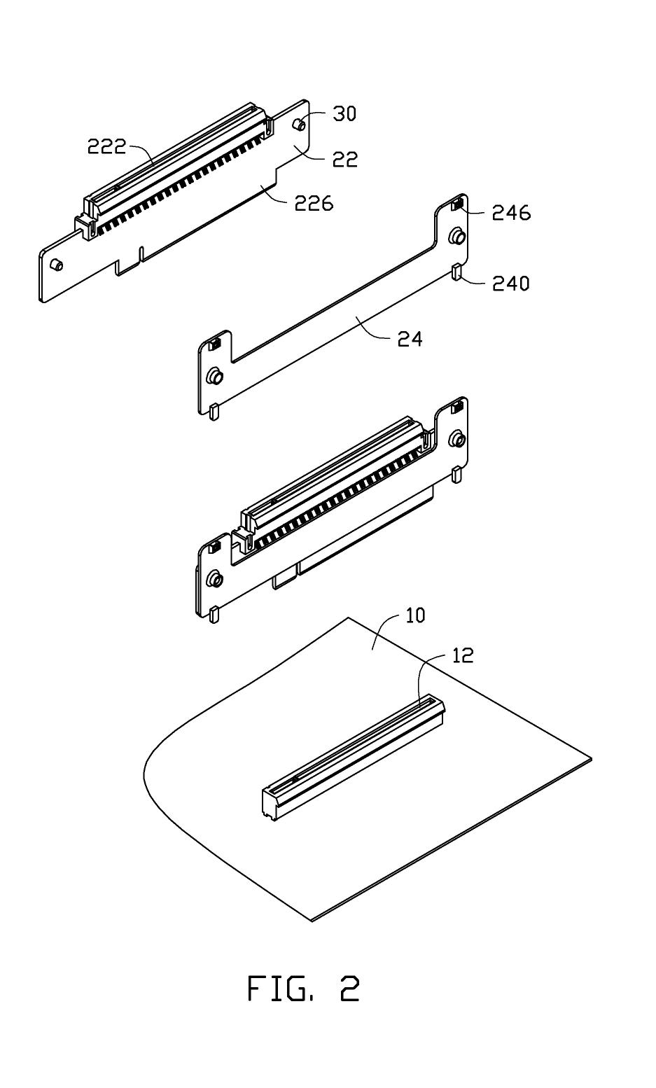

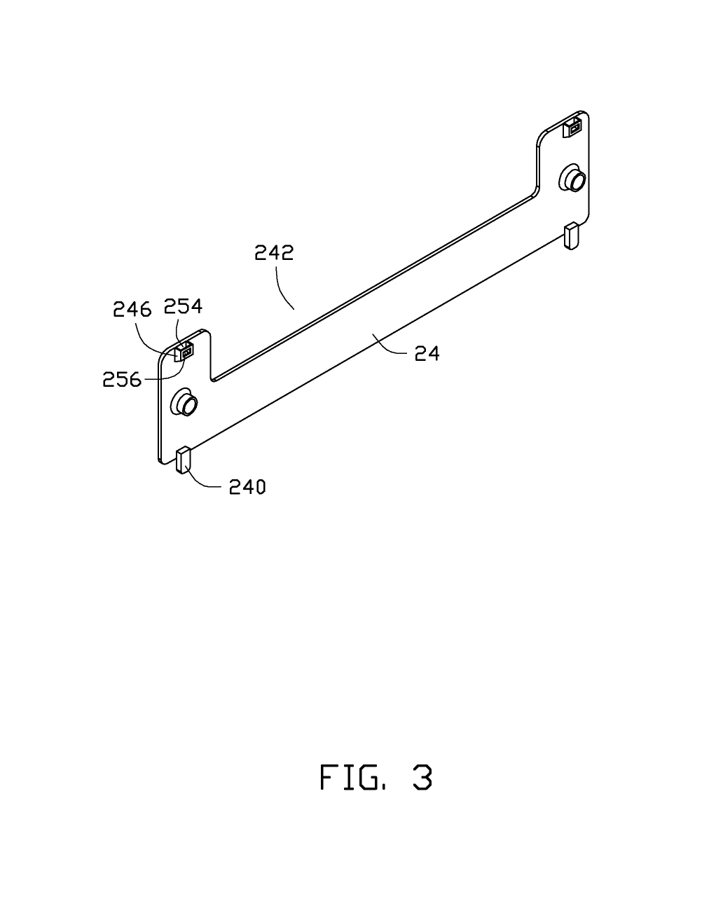

FIGS. 1 to 3 show an embodiment of a riser card assembly 20. The riser card assembly 20 is mounted to a motherboard 10.

The motherboard 10 forming a socket 12.

The riser card assembly 20 includes two riser cards 22 and two fixing members 24.

Each riser card 22 includes a plate 220, a first connector 222 connected to a top side of the plate 220, a second connector 224 connected to a lateral side of the plate 220, and an edge connector 226 extending down from a bottom side of the plate 220.

Each fixing member 24 is a flat board defining an opening 242 in a center of a top side. Two pins 240 extend down from opposite ends of a first lateral side of the fixing member 24, opposite the opening 242. Two receiving portions 246 protrude from the first lateral side of the fixing member 24 and at opposite ends of the opening 242. Each receiving portion 246 defines a receiving space 254 extending through a top surface of the receiving portion 246, and an engaging hole 256 communicating with the receiving space 254 and extending through a side of the receiving portion 246 opposite to the fixing member 24.

Two screws 30 extend through each plate 220 and then engage in one of the fixing members 24, to fix the riser card 22 to a second lateral side of the fixing member 24 opposite to the receiving portions 246. The first connectors 222 are received in the corresponding openings 242.

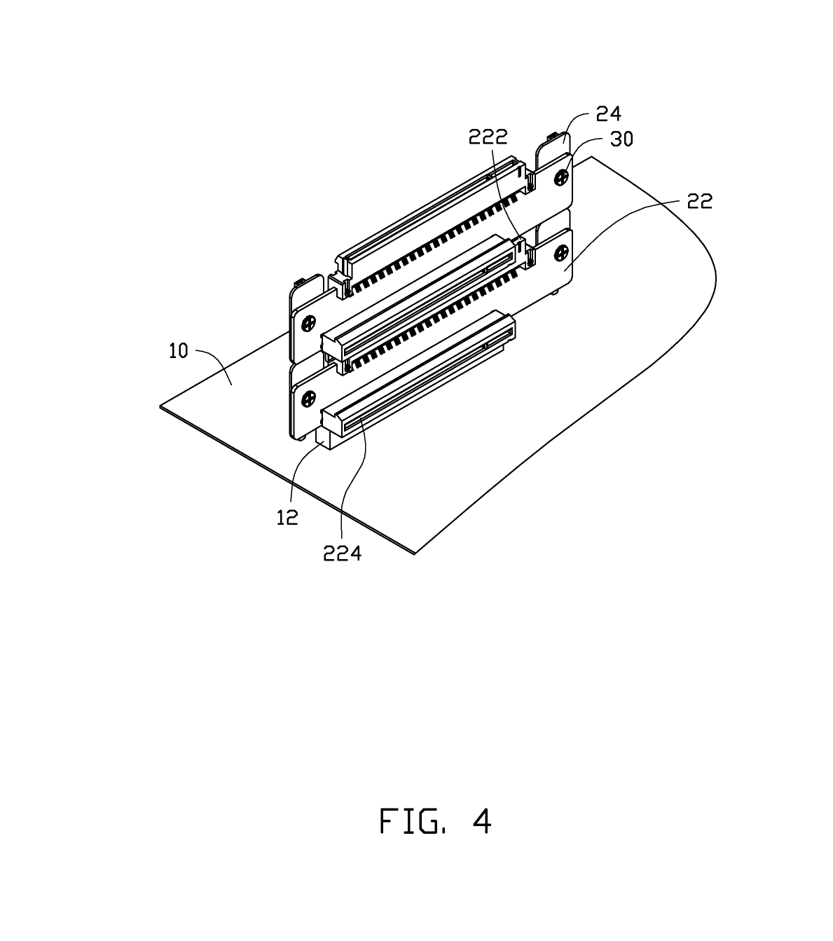

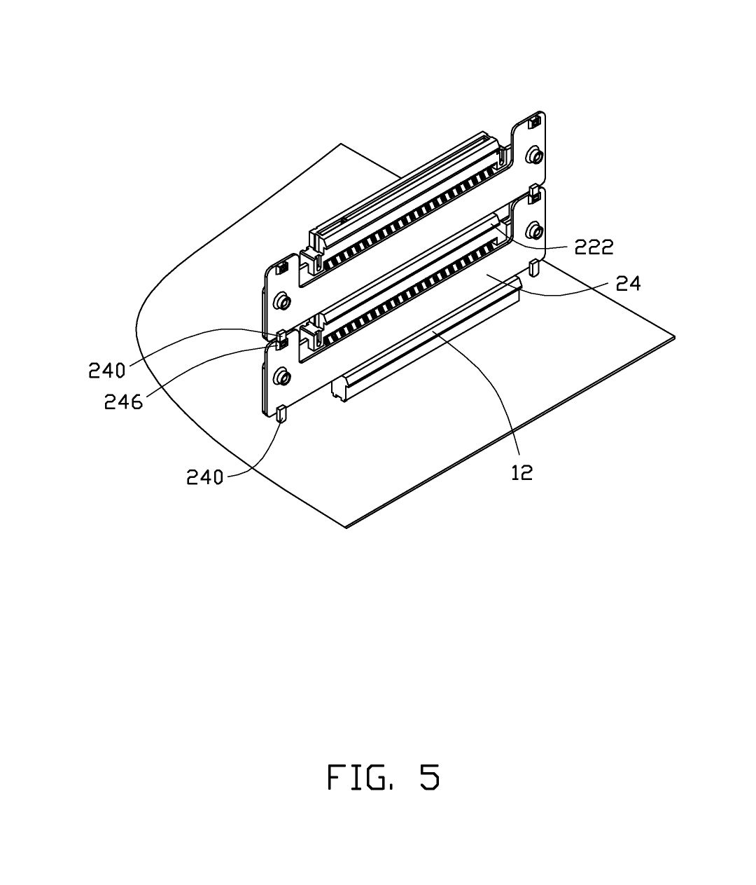

FIGS. 4 and 5 show that in assembly, the edge connector 226 of one of the riser cards 22 is engaged in the first connector 222 of the other riser card 22. At the same time, the pins 240 of the upper fixing member 24 are engaged in the receiving spaces 254 of the lower fixing member 24. Therefore, the riser cards 22 are electrically connected and fixed to each other. The edge connector 226 of the lower riser card 22 is then engaged in the socket 12, thereby electrically connecting the riser card assembly 20 to the motherboard 10.

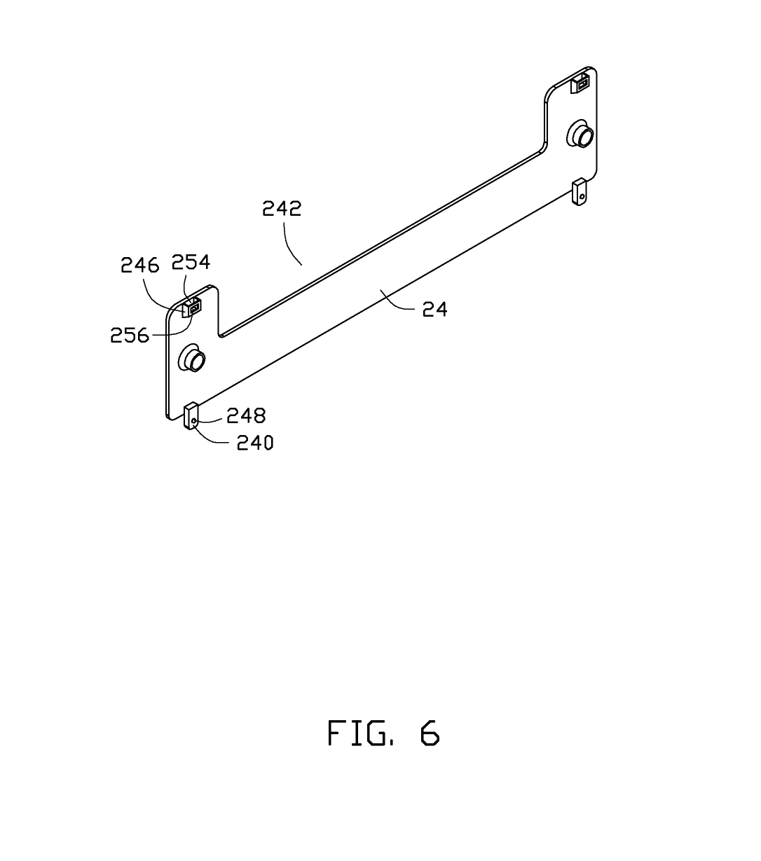

FIG. 6 shows that in another embodiment, a resilient projection 248 protrudes from each pin 240 to be engaged in the engaging hole 256 of one of the receiving portions 246.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. A riser card assembly, comprising:
two riser cards each comprising a plate, wherein a first connector is mounted to a top side of the plate, a second connector is mounted to a lateral side of the plate, an edge connector extends down from a bottom side of the plate; and
two fixing members, wherein a receiving portion protrudes from a first lateral side of each fixing member, a pin extends down from a bottom side of each fixing member;
wherein the riser cards are fixed to second lateral sides of a corresponding one of the fixing members opposite to the receiving portions, the edge connector of one of the riser cards is capable of being engaged in the first connector of the other riser card, the pin of one of the fixing members is capable of being engaged in the receiving portion of the other fixing member.

2. The riser card assembly of claim 1, wherein each fixing member defines an opening in a top side to receive the first connector of a corresponding one of the riser cards.

3. The riser card assembly of claim 1, wherein each receiving portion defines a receiving space in a top surface to receive a corresponding one of the pins, and an engaging hole communicating with the receiving space in a side of the receiving portion, a resilient projection protrudes from the pin to be engaged in the engaging hole.
